(19) United States
(12) Patent Application Publication
(10) Pub. No.: US 2014/0361324 A1
(43) Pub. Date: Dec. 11, 2014

(54) SEMICONDUCTOR LIGHT EMITTING DEVICE

(71) Applicant: KABUSHIKI KAISHA TOSHIBA, Tokyo (JP)

(72) Inventors: Naoya USHIYAMA, Nomi (JP); Kazuhiro INOUE, Komatsu (JP); Kenji SHIMOMURA, Kitakyushu (JP); Tetsuro KOMATSU, Nonoichi (JP); Toshihiro KUROKI, Nonoichi (JP); Toshihiro KOMEYA, Nonoichi (JP); Kazuhiro TAMURA, Nonoichi (JP); Yoshiharu TSUBOI, Hakusan (JP); Teruo TAKEUCHI, Kanazasa (JP); Kazuhisa IWASHITA, Kitakyushu (JP)

(21) Appl. No.: 14/194,602

(22) Filed: Feb. 28, 2014

(30) Foreign Application Priority Data
Jun. 11, 2013 (JP) 2013-123196

(51) Int. Cl. H01L 33/60; H01L 33/56

(52) U.S. Cl. CPC H01L 33/60; H01L 33/56
USPC 257/98

(57) ABSTRACT

A light emitting device includes a light emitting element disposed on a portion of a first lead frame element, a first resin including a fluorescent material, and a second resin. The first resin is above the light emitting element. The second resin is between the first resin and the first lead frame element. In some embodiments, the second resin includes a filler material that reflects light emitted by the light emitting element. In some embodiments, the light emitting device includes a protective diode connected in reverse parallel with the light emitting element. In some embodiments, a transparent resin may be disposed first and second resins.

### CROSS-REFERENCE TO RELATED APPLICATION

This application is based upon and claims the benefit of priority from Japanese Patent Application No. 2013-123196, filed Jun. 11, 2013, the entire contents of which are incorporated herein by reference.

### FIELD

Embodiments described herein relate generally to a semiconductor light emitting device.

### BACKGROUND

A semiconductor light emitting device on which a semiconductor light emitting element such as a Light Emitting Diode (LED) is provided has been used as a backlight of a liquid crystal display or the like.

A semiconductor light emitting device can have a structure referred to as “surface-mounted type” structure, where a semiconductor light emitting element is fixed to a lead frame and then sealed by a resin or the like, for example. In the semiconductor light emitting device, there may be a case where some light emitted by the semiconductor light emitting element falls on the lead frame or a substrate on which the semiconductor light emitting element is disposed. Emitted light which falls on the lead frame or substrate is generally not output from the semiconductor light emitting device, consequently there is a light absorption (loss) and overall light extraction efficient of the light emitting device is reduced.

### DESCRIPTION OF THE DRAWINGS

FIG. 1 is a cross-sectional view of a semiconductor light emitting device according to a first embodiment.

FIG. 2 is a cross-sectional view of a semiconductor light emitting element and a filler-containing resin at a portion of the semiconductor light emitting device according to the first embodiment.

FIG. 3 is a schematic view depicting light emitted from the semiconductor light emitting element according to the first embodiment.

FIG. 4 is a schematic view of the cross-sectional structure of a semiconductor light emitting device according to a comparison example and light emitted from a semiconductor light emitting element in the comparison example.

FIG. 5 is a cross-sectional view of a semiconductor light emitting device according to a second embodiment.

### DETAILED DESCRIPTION

According to an embodiment, there is provided a semiconductor light emitting device which enhances light extraction efficiency.

In general, according to one embodiment, light emitting device includes a light emitting element having a first surface disposed on a portion of a first lead frame element. A first resin includes a fluorescent material that may for example absorb a wavelength of light emitted by the light emitting element and emit light at a second wavelength. The first resin including the fluorescent material is disposed above the light emitting element in a direction orthogonal to the first surface of the light emitting element. A second resin is disposed between the first resin and the first lead frame element. The second resin in some embodiments may include a filler material that reflects light at the wavelength of light emitted by the light emitting element. In some embodiments, the filler material may comprise titanium dioxide. The second resin in may be transparent to the wavelength of light emitted by the light emitting element.

According to another embodiment, a semiconductor light emitting device includes: a lead frame element; and a light emitting element which includes a silicon substrate whose upper surface and side surface are covered with a light reflection material such as a reflective metal layer, and a light emitting part which is provided on the silicon substrate with the light reflection material interposed therebetween, the light emitting element being provided on the providing portion.

Hereinafter, exemplary embodiments are described with referring to drawings. In the description made hereinafter, common parts having a similar constitution are indicated by the same symbol in all drawings. Size ratios applicable to the embodiments depicted in the drawings are not limited to the ratios illustrated in the drawings. Further, these embodiments are exemplary and do not limit the present disclosure.

### First Embodiment

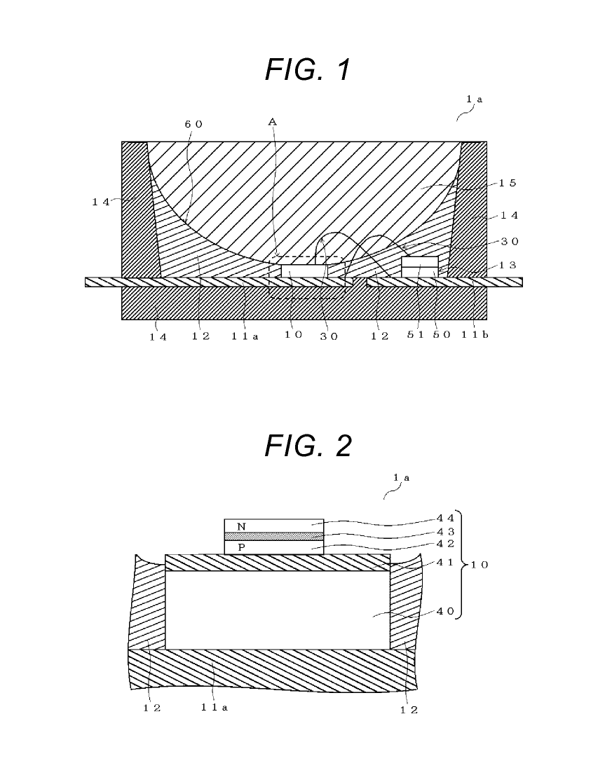

The structure of a semiconductor light emitting device 1a of the first embodiment is described with referring to FIG. 1 and FIG. 2. FIG. 1 is a cross-sectional view of the semiconductor light emitting device 1a according to the first embodiment, and FIG. 2 is a cross-sectional view of a semiconductor light emitting element 10 and a resin 12 at a portion A of the semiconductor light emitting device 1a according to the first embodiment. The resin 12 includes a filler material.

The semiconductor light emitting device 1a includes: the semiconductor light emitting element (light emitting element) 10; a lead frame (first lead frame element) 11a; a lead frame (second lead frame element) 11b; a resin (filler resin) 12 including a filler; a zener diode (protection element) 13; a sealing resin 14; a resin 15 (fluorescent resin) including a fluorescent material; and connection lines (wires) 30. The semiconductor light emitting element 10 includes: a silicon substrate 40; a metal layer (light reflecting layer) 41; a P-type semiconductor layer 42; a light emitting layer 43; and an N-type semiconductor layer 44.

A possible structure of the semiconductor light emitting element 10 is described. The metal layer 41 constituting a light reflection layer is formed on the silicon (Si) substrate 40. The P-type semiconductor layer 42 and the N-type semiconductor layer 44 are made of gallium nitride (GaN), for example. Layers 42, 43, and 44 are sequentially formed (stacked) on the metal layer 41. The light emitting layer 43 is formed between P-type semiconductor layer 42 and the N-type semiconductor layer 44. In some embodiments, the position of the P-type semiconductor layer 42 the N-type semiconductor layer 44 is may be reversed—that is, N-type layer 44 may on the metal layer 41 such that the layer sequence is layer 41, layer 44, layer 43, layer 42 rather the depicted sequence in FIG. 1. Although silicon substrate 40 is used in the semiconductor light emitting element 10 according to this embodiment, the substrate for the semiconductor light emitting element 10 is not limited to silicon, and other semiconductor substrate types may be used. For the purpose of increasing light extraction efficiency of the semiconductor light emitting device 1a, a surface (or surfaces) of the semiconductor light emitting element 10 may have a roughened surface (not specifically depicted).

The semiconductor light emitting element 10 is mounted on the lead frame 11a (more specifically a surface of the lead frame 11a) by soldering (not shown) or the like. The silicon substrate 40 side of the semiconductor light emitting element 10 is mounted on the lead frame 11a. That is, in this embodiment, the N-type semiconductor layer 44 forms an upper surface of the semiconductor light emitting element 10.

The zener diode 13 is mounted on the lead frame 11b by soldering or the like. The zener diode 13 includes a P-type semiconductor layer 50 and an N-type semiconductor layer 51 which are each made of silicon in this embodiment. The zener diode 13 is mounted on the lead frame 11b such that the N-type semiconductor layer 51 forms an upper surface of the zener diode 13, that is, P-type semiconductor layer 50 is between N-type semiconductor layer 51 and the lead frame 11b.

The lead frame 11a and the lead frame 11b are made of a metal material such as copper, for example, and in some embodiments the lead frame 11a and the lead frame 11b are plated with silver (Ag) or the like so as to increase the adhesiveness thereof with the resin 12 and also a reflectivity thereof.

The zener diode 13 is connected in reverse parallel with the semiconductor light emitting element 10. Although the connection lines 30 which connect the semiconductor light emitting element 10 and the zener diode 13 to each other are preferably made of gold (Au) in this embodiment, the lines 30 may be also made of silver or other conductive metals.

The resin 12 including filler material covers a side surface of the silicon substrate 40, while leaving an upper surface (e.g., N-type semiconductor layer 44) of the semiconductor light emitting element 10 exposed. In this case, the resin 12 may also cover a side surface of the metal layer 41. The resin 12 may also cover a side surface of the N-type semiconductor layer 44. That is, the resin 12 may cover the entire side surface of semiconductor light emitting element 10. But to improve efficiency of extracting light from the side surface of the semiconductor light emitting element 10, it is desirable that the side surface of the N-type semiconductor layer 44, the side surface of the light emitting layer 43, and the side surface of the P-type semiconductor layer 42 are exposed, that is not covered with resin 12, which includes filler material which reflects light emitted from semiconductor light emitting element 10.

The resin 12 is formed on the lead frame 11a and the lead frame 11b to cover the zener diode 13. In this example, the filler-containing resin 12 may be disposed on the lead frame 11a or on the lead frame 11b to have an upper surface (upper surface 60) having a curved shape by making use of a surface tension thereof. For example, the upper surface 60 of the filler-containing resin 12 can have a concave parabolic curved shape with the semiconductor light emitting element 10 positioned at a bottom of the recessed (concave) portion.

The resin 12 is a mixture of transparent silicone, which is a polymer compound containing silicon, and fine particles (filler) of titania (titanium dioxide (TiO₂)), which function as a light reflection material. It is sufficient that filler has a light reflecting property, and the resin 12 may include fillers other than titania. The content of titania included within resin 12 is 10 wt % to 70 wt %, for example.

Although a resin 12 which contains filler is used as the resin in this embodiment, any material which reflects a light may be used in place of a filler-containing resin 12 when appropriate. For example, a compound material such as a non-conductive metal oxide may be used in place of filler-containing resin 12 when appropriate.

The resin 15 includes fluorescent material and is formed on the semiconductor light emitting element 10 and the resin 12. As depicted in FIG. 1, the resin 15 can be formed such that the recessed portion of the resin 12 is filled with the resin 15.

While allowing an upper surface of the resin 15 to be exposed, the lead frame 11a, the lead frame 11b, and the resin 12 are sealed by a sealing resin 14—that is, sealing resin 14 is used to cover certain exposed portions of lead frame 11a, lead frame 11b, and resin 12. For example, as in FIG. 1, sealing resin 14 may cover side surfaces of resin 12, portions of the upper surface of lead frame 11a and lead frame 11b, and back-side surface of lead frame 11a and lead frame 11b.

For the purpose of increasing light extraction efficiency of the semiconductor light emitting device 1a, a surface of the fluorescent material-containing resin 15 may be formed into a rough surface (not specifically depicted).

As a base material of the filler-containing resin 12 and a base material of the fluorescent material-containing resin 15, a phenyl-based silicone resin, a dimethyl-based silicone resin, an acrylic-based resin or the like may be used, for example.

A method of forming the semiconductor light emitting element 10 is described hereinafter. The P-type semiconductor layer 42, the light emitting layer 43, and the N-type semiconductor layer 44 are formed by an epitaxial growth on a substrate for growth (a silicon substrate, for example, not shown) using a Metal Organic Chemical Vapor Deposition (MOCVD) method or the like. The P-type semiconductor layer 42 and the N-type semiconductor layer 44, however, may be also formed using a Physical Vapor Deposition (PVD) method such as sputtering or the like.

The metal layer 41 is formed on the P-type semiconductor layer 42 by sputtering or the like, the silicon substrate 40 is adhered to the metal layer 41, and the substrate for growth is then removed by wet etching or the like.

Thereafter, apart of the N-type semiconductor layer 44, a part of the light emitting layer 43, and a part of the P-type semiconductor layer 42 are removed by etching so that a part of a surface of the metal layer 41 is exposed. A first electrode is formed on the N-type semiconductor layer 44, and a second electrode is formed on an exposed part of the exposed metal layer 41. The semiconductor light emitting element 10 is thus formed in accordance with the above-mentioned steps.

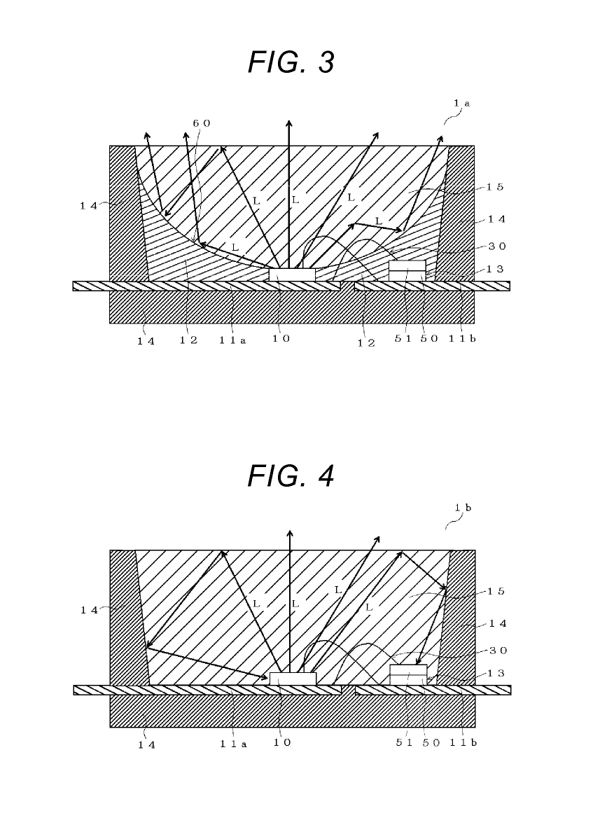

Next, operation of the semiconductor light emitting device 1a is described with referring to FIG. 3. FIG. 3 is a schematic view showing advancing directions of a light emitted from the semiconductor light emitting element 10 according to the first embodiment. When a voltage is applied to the semiconductor light emitting element 10 in the forward direction, a light L is emitted from the light emitting layer 43.

In the case of the semiconductor light emitting device 1a according to this embodiment, when a positive voltage is applied to the semiconductor light emitting device 1a using the lead frame 11a electrically connected to the P-type semiconductor layer 42 as an anode and the lead frame 11b electrically connected to the N-type semiconductor layer 44 as a cathode, the light emitting layer 43 of the semiconductor light emitting element 10 emits a light. A blue light is emitted from the semiconductor light emitting element 10, for example.

Although some of the light L emitted from the light emitting layer 43 advances in the downward direction, that is, in the direction toward the silicon substrate 40, these lights L are reflected by the metal layer 41. Accordingly, these lights L are not absorbed by the silicon substrate 40, and may be extracted from an upper surface of the semiconductor light emitting device 1a.

With respect to the light L which advances towards the outside of the semiconductor light emitting device 1a, some of the light is emitted to the outside (air) without change, but some of the light is subjected to a wavelength conversion and is converted into a yellow light, for example, by the fluorescent material included in resin 15. Some of the light may also be scattered by a fluorescent material in resin 15 (yellow light, for example), some of the light is reflected at the interface between the resin 15 and the outside (e.g., the upper surface of resin 15), or the like. Some of the light L which is subjected to the wavelength conversion and disperses at an angle of 360°, some of the light L which is scattered by the fluorescent material and some of the light L which is reflected at the interface between resin 15 and the outside advance toward the lead frame 11a or the lead frame 11b. The light L which advances in the direction of the lead frame 11a or the lead frame 11b may be reflected at the upper surface 60 of the resin 12, and consequently advances towards the outside of the semiconductor light emitting device 1a again.

The zener diode 13 is connected in reverse parallel with the semiconductor light emitting element 10. Accordingly, the zener diode 13 plays a role of preventing the semiconductor light emitting device 1a from being damaged when a surge current or static electricity flows into the semiconductor light emitting device 1a.

As described above, the light L emitted by the semiconductor light emitting element 10 is emitted towards the outside of the semiconductor light emitting device 1a.

The advantageous effects of the semiconductor light emitting device 1a are described with reference to a semiconductor light emitting device 1b according to a comparison example.

FIG. 4 is a schematic view showing the cross-sectional structure of the semiconductor light emitting device 1b according to the comparison example and light emitted from a semiconductor light emitting element 10 of the semiconductor light emitting device 1b.

The semiconductor light emitting device 1b according to the comparison example differs from the semiconductor light emitting device 1a according to the first embodiment with respect to a point that the semiconductor light emitting device 1b does not include a resin 12 that includes filler material. Other structures and the basic manner of operations of the semiconductor light emitting device 1b according to the comparison example are similar to the corresponding structures and basic manner of operations of the semiconductor light emitting device 1a according to the first embodiment. Accordingly, the repeated description of these constitutions and the manner of operation has been omitted.

In the case of the semiconductor light emitting device 1b, due to the wavelength conversion of an emitted light into a yellow light, for example, in resin 15 including fluorescent material, the scattering of an emitted light by a fluorescent material in the resin 15, the reflection of an emitted light on an interface between the resin 15 and the outside, or the like, a light L which is emitted from the semiconductor light emitting element 10 and advances in the direction of a lead frame 11a and a lead frame 11b may reach silicon substrate 40 or zener diode 13. That is, a yellow light which is scattered in resin 15, and a blue light which is reflected at the interface between the resin 15 and the outside may reach the silicon substrate 40 or the zener diode 13 because no resin 12 is present in semiconductor light emitting device 1b to reflect such light away from these elements.

Silicon used for forming the silicon substrate 40 and the zener diode 13 generally his highly absorbing of light at relevant wavelengths for semiconductor light emitting devices 1a and 1b. Accordingly, some of the light L impinging on the silicon substrate 40 and the zener diode 13 is absorbed. Some of the light L emitted from the semiconductor light emitting element 10 thus effectively disappears in the semiconductor light emitting device 1b, thus lowering light extraction efficiency of the semiconductor light emitting device 1b.

In the case of the semiconductor light emitting device 1a, as described previously, the light L which advances in the direction of the lead frame 11a and the lead frame 11b is reflected by the filler in resin 12 so that the light is reflected to the outside of the semiconductor light emitting device 1a. Accordingly, it is possible to reduce the amount of light L that is absorbed by the silicon substrate 40 and the zener diode 13. That is, compared to the semiconductor light emitting device 1b, light extraction efficiency of the semiconductor light emitting device 1a will be increased.

When the concentration of the filler contained in the resin 12 in the vicinity of upper surface 60 is higher than the concentration of filler contained in resin 12 away from upper surface 60 (that is, in resin 12 closer to lead frame 11a/11b), the above-mentioned advantageous effect is increased significantly.

When the resin 12 has a concave parabolic curved shape, the light L may be also be more efficiently extracted from an upper portion of the semiconductor light emitting element 10. That is, this structure also offers an advantageous effect that uniformity of the light on a light extraction surface of the semiconductor light emitting device 1a is increased.

In general, the adhesion between the resins will be higher than the adhesion between the semiconductor layers and the resin(s). Accordingly, by providing the resin 12, it is possible to substantially increase adhesion between the semiconductor light emitting element 10 and the fluorescent material-containing resin 15. As a result, the lowering of brightness caused by the separation (peeling off) of the semiconductor light emitting element 10 from the fluorescent material-containing resin 15 or the consequential lowering of reliability of the semiconductor light emitting device 1a may be suppressed.

By selecting a filler-containing resin 12 and a fluorescent material-containing resin 15 such that a linear expansion coefficient of the filler-containing resin 12 is less than a linear expansion coefficient of the fluorescent material-containing resin 15, with increasing temperatures, a compression force will act in the direction of the semiconductor light emitting element 10 and work to prevent separation of the semiconductor light emitting element 10 from the resin 15. As a result, any lowering of brightness that might be caused by the peeling off of the semiconductor light emitting element 10 from the fluorescent material-containing resin 15 or the lowering of reliability of the semiconductor light emitting device 1a may be suppressed.

A light reflectance of silver is approximately 90%, and a light reflectance of gold is approximately 60%. That is, the light reflectance of silver is higher than the light reflectance of gold. Accordingly, by using silver for forming the lines 30, the light extraction efficiency of the semiconductor light emitting device 1a may be further enhanced.

By using the filler-containing resin 12 and the fluorescent material-containing resin 15 such that the modulus of elasticity of the filler-containing resin 12 is less than the modulus of elasticity of the fluorescent material-containing resin 15, the occurrence of cracks due to an external stress may be prevented so that a mechanical strength of a peripheral portion of the semiconductor light emitting device 1a may be enhanced.

The resin 12 includes titania which is an inorganic material and hence, the resin 12 including titania has a higher thermal conductivity than the resin 15 including the fluorescent material. Accordingly, a heat radiation property of the semiconductor light emitting device 1a may be improved.

By selecting the resin 12 and the resin 15 such that thixotropy of the filler-containing resin 12 is greater than thixotropy of the resin 15, it is possible to keep a shape of the resin 12 in a stable manner when formed. Accordingly, the resin 12 having a large thickness may be uniformly formed and hence, the resin 15 having a relatively small thickness may be uniformly formed, whereby the brightness of the semiconductor light emitting device 1a may be made stable.

### Second Embodiment

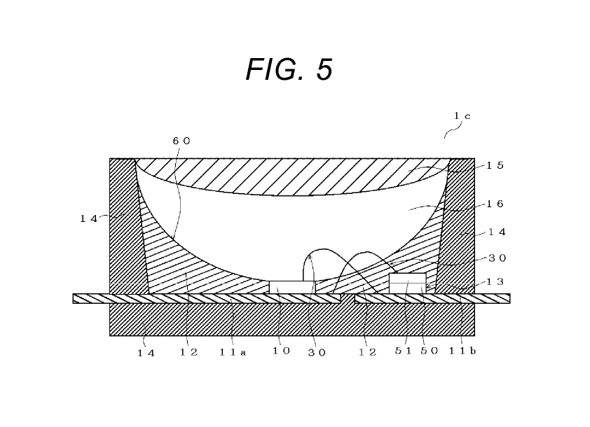

Hereinafter, a semiconductor light emitting device 1c according to the second embodiment is described with referring to FIG. 5. FIG. 5 is a cross-sectional view of the semiconductor light emitting device 1c according to the second embodiment.

FIG. 5 is a cross-sectional view showing the cross-sectional structure of the semiconductor light emitting device 1c according to the second embodiment. The semiconductor light emitting device 1c differs from the semiconductor light emitting device 1a with respect to inclusion of a transparent resin 16 between semiconductor light emitting element 10 and resin 15. That is, on lead frame 11a and lead frame 11b, a three-layered structure including a resin 12, the transparent resin 16, and the resin 15 is formed. Silicone can be used for forming the transparent resin 16, for example.

The manner of operation of the semiconductor light emitting device 1c is substantially equal to the manner of operation of the semiconductor light emitting device 1a

The advantageous effects of the semiconductor light emitting device 1c are described. As has been already described in the description of the semiconductor light emitting device 1a according to the first embodiment, for example, some of a light L which is a blue light and is emitted from the semiconductor light emitting element 10 is returned to the semiconductor light emitting element 10 due to the scattering of the light after the wavelength conversion of the emitted light L to a yellow light in the fluorescent material in resin 15 or the reflection of the emitted light L at an interface between the resin 15 and the outside.

Gallium nitride used for forming a P-type semiconductor layer 42 and an N-type semiconductor layer 44 absorbs light at the relevant wavelengths, although the degree of light absorbance of gallium nitride is typically less than the degree of light absorbance of the silicon substrate 40. The light impinging on gallium nitride may be absorbed by crystal defects in gallium nitride. A blue light having a short wavelength is strongly absorbed by gallium nitride. The light L which is returned to the semiconductor light emitting element 10 is not completely reflected by a metal layer 41.

In the case of the semiconductor light emitting device 1c, the transparent resin 16 is formed between the semiconductor light emitting element 10 and the resin 15. Accordingly, in the semiconductor light emitting device 1c, a distance between the semiconductor light emitting element 10 and the fluorescent material-containing resin 15 may be increased so that an amount of light L which is scattered or reflected in the resin 15 in the course of returning to the semiconductor light emitting element 10 may be substantially decreased, as compared to the semiconductor light emitting device 1a. Accordingly, light absorbed by the semiconductor light emitting element 10 may be further decreased so that light extraction efficiency may be increased. Furthermore, the distance between the semiconductor light emitting element 10 and the fluorescent resin 15 is made larger and hence, a light emitted from the semiconductor light emitting element 10 is spread and dispersed so as not to be concentrated on a surface of the resin 15. Hence, the generation of heat due to the absorption of light by the fluorescent material may be decreased.

When the resin 15 including fluorescent material is formed in the vicinity of the semiconductor light emitting element 10, a blue light falls on a fluorescent material in the vicinity of the semiconductor light emitting element 10 in a relatively concentrated manner. Consequently, there is a possibility that color variation occurs in the light extracted to the outside. In the case of the semiconductor light emitting device 1c, however, the transparent resin 16 is formed directly above the semiconductor light emitting element 10 and hence, a blue light emitted from the semiconductor light emitting element 10 more diffusely falls on the resin 15. Accordingly, the color breakup of the light extracted to the outside of the semiconductor light emitting device 1c may be suppressed.

The semiconductor light emitting device 1c may also acquire the substantially same advantageous effects as the semiconductor light emitting device 1a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device, comprising:
a light emitting element having a first surface disposed on a portion of a first lead frame element;
a first resin including a fluorescent material and disposed above the light emitting element in a direction orthogonal to the first surface of the light emitting element; and
a second resin disposed between the first resin and the first lead frame element.

2. The light emitting device according to claim 1, wherein the light emitting element includes:
a silicon substrate having an upper surface on which a light reflecting layer is disposed; and
a light emitting layer disposed on the silicon substrate via the light reflecting layer.

3. The light emitting device according to claim 2, wherein the second resin includes a filler that reflects light at a wavelength emitted by the light emitting element, and
the second resin is disposed on a side surface of the light emitting element.

4. The light emitting device according to claim 3, wherein the entire upper surface of the silicon substrate is covered with the light reflecting layer, and the entire side surface of the silicon substrate is covered with the second resin.

5. The light emitting device according to claim 3, wherein a concentration of the filler in the second resin is greater near an upper surface of the second resin on which the first resin is disposed than a concentration of the filler in the second resin near the first lead frame.

6. The light emitting device according to claim 1, wherein the second resin has an upper surface with a concave parabolic shape.

7. The light emitting device according to claim 1, further comprising:
a third resin being substantially transparent to a wavelength of light emitted by the light emitting element and disposed on an upper surface of the second resin, and
the first resin is disposed on an upper surface of the third resin.

8. The light emitting device according to claim 7, wherein the upper surface of the third resin has a concave shape.

9. The light emitting device according to claim 7, further comprising:
a diode disposed on a portion of a second lead frame element and in the second resin, wherein
the diode is electrically connected in reverse parallel to the light emitting element.

10. The light emitting device according to claim 9, wherein the diode and the light emitting element are electrically connected by wires extending through at least one of the second and third resins.

11. The light emitting device according to claim 10, wherein the wires comprise a material that reflects light at a wavelength emitted by the light emitting element.

12. The light emitting device according to claim 1, further comprising:
a diode disposed on a portion of a second lead frame element and in the second resin, wherein
the diode is electrically connected in reverse parallel to the light emitting element.

13. The light emitting device according to claim 12, wherein the diode and the light emitting element are electrically connected by wires extending through at least one of the first and second resins.

14. The light emitting device according to claim 13, wherein the wires comprise silver.

15. A light emitting device, comprising:
a light emitting element disposed on a first portion of a surface of a first lead frame element;
a filler resin including a filler material that reflects light at a wavelength emitted by the light emitting element, the filler resin being disposed on a side surface of the light emitting element and a second portion of the surface of first lead frame element; and
a fluorescent resin including a fluorescent material and disposed on an upper surface of the filler resin that is opposite the second portion of the surface of the first lead frame element and an upper surface the light emitting element that is opposite the first portion of the surface of the first lead frame element.

16. The light emitting device of claim 15, wherein a distance between the upper surface of the filler resin and the surface of the first lead frame element increases with an increase in a distance from the light emitting element along a direction parallel to the surface of the first lead frame element.

17. The light emitting device of claim 16, wherein the upper surface of the filler resin has a concave parabolic shape.

18. The light emitting device of claim 16, further comprising:
a transparent resin disposed between the upper surface of the filler resin and the fluorescent resin and between the upper surface of the light emitting element and the fluorescent resin, the transparent resin being substantially transparent to the wavelength of light emitted by the light emitting element.

19. A light emitting device, comprising:
a light emitting element disposed on a surface of a first lead frame element;
a diode disposed on a second lead frame element that is separated from the first lead frame element;
a first wire electrically connecting the light emitting element to an anode of the diode;
a second wire electrically connecting the light emitting element to a cathode of the diode;
a first resin including a filler material that reflects light at a wavelength emitted by the light emitting element, the first resin being disposed on a side surface of the light emitting element, the first lead frame element, and the second lead frame element and covering the diode; and
a second resin including a fluorescent material disposed above the first resin in a direction orthogonal the surface of the first lead frame element, wherein
wherein a distance between an upper surface of the first resin and the surface of the first lead frame element increases with an increase in a distance from the light emitting element along a direction parallel to the surface of the first lead frame element.

20. The light emitting device of claim 19, further comprising:
a third resin that is substantially transparent to the wavelength of light emitted by the light emitting element, the third resin being disposed between the second resin and the upper surface of the first resin and disposed between the light emitting element and the second resin.
